(19) United States
(12) Patent Application Publication
(10) Pub. No.: US 2009/0098725 A1
(43) Pub. Date: Apr. 16, 2009

(54) METHOD FOR FABRICATING SEMICONDUCTOR DEVICE

(75) Inventors: Ki-Won Nam, Ichon-shi (KR); Hee-Seung Shin, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 11/965,574

(22) Filed: Dec. 27, 2007

(30) Foreign Application Priority Data
Oct. 11, 2007 (KR) 10-2007-0102545

(51) Int. Cl. H01L 23/522

(52) U.S. Cl. 438/618; 257/E23.145

(57) ABSTRACT

A method for fabricating a semiconductor device, the method includes forming a metal line over a substrate, the metal line having a stacked structure of a conductive layer and a barrier layer, forming an inter-metal dielectric layer over the barrier layer, etching the inter-metal dielectric layer by using a carbon-rich CF-based gas through a target opening the barrier layer, and forming a contact hole by overetching the barrier layer to a given depth by using a gas containing a smaller amount of carbon than in the etching of the inter-metal dielectric layer.

### CROSS-REFERENCE TO RELATED APPLICATIONS

The present invention claims priority of Korean patent application number 10-2007-0102545, filed on Oct. 11, 2007, which is incorporated by reference in its entirety.

### BACKGROUND OF THE INVENTION

The present invention relates to a method for fabricating a semiconductor device, and more particularly, to a method for forming a metal line of a semiconductor device.

In forming a metal line of a semiconductor device, stop on titanium nitride (TiN) (SOT) is used for a lower metal line in interconnection between metal lines.

The SOT prevents a contact with the lower metal layer by making an etching stop at an anti-reflection coating (ARC) TiN in a contact hole etching process for interconnection between metal lines. The ARC TiN is a barrier layer serving as an anti-reflection over the bottom metal line.

FIG. 1 illustrates a cross-sectional view of a typical semiconductor device.

Referring to FIG. 1, a metal layer 12 for a metal line is formed over a substrate 11. A barrier layer 13 for anti-reflection is formed over the metal layer 12. An interlayer dielectric layer 14 is formed over the barrier layer 13. A contact hole 15 is formed for interconnection of a metal line M1. The metal layer 12 may be formed of aluminum, and the barrier layer 13 may be formed of titanium nitride (TiN).

Since the barrier layer 13 is formed over the metal layer 12 and the etching is stopped at the barrier layer 13 when forming the contact hole 15, the metal layer 12 can be prevented from being exposed to air and oxidized.

However, in forming the contact hole 15, punch phenomenon may occur due to a barrier layer 13 having a low thickness and a low etching rate. Further, if an etch target is reduced so as to prevent the punch phenomenon, a contact-not-open phenomenon may occur. If the barrier layer 13 is formed thickly so as to prevent the punch phenomenon, a photoresist layer may be excessively lost due to deficient etch margin of the photoresist layer in etching the metal lines, and the top of the contact hole may sustain loss. That is, an upper dielectric layer of the contact hole may be lost, and lines may be shorted since neighboring metal lines are attached.

### SUMMARY OF THE INVENTION

Embodiments of the present invention are directed to providing a method for fabricating a semiconductor device, which can prevent a punch phenomenon of a barrier layer in forming a contact hole for interconnection between metal lines and can prevent a contact-not-open phenomenon, thereby improving the reliability of the semiconductor device.

In accordance with an aspect of the present invention, there is provided a method for fabricating a semiconductor device. The method includes: forming a metal line over a substrate; the metal line having a stacked structure of a conductive layer and a barrier layer; forming an inter-metal dielectric layer over the barrier layer; etching the inter-metal dielectric layer by using a carbon-rich CF-based gas through a target opening the barrier layer; and forming a contact hole by overetching the barrier layer to a given depth by using a gas containing a smaller amount of carbon than in the etching of the inter-metal dielectric layer.

### BRIEF DESCRIPTION OF THE DRAWINGS

FIG. 1 illustrates a cross-sectional view of a typical semiconductor device.

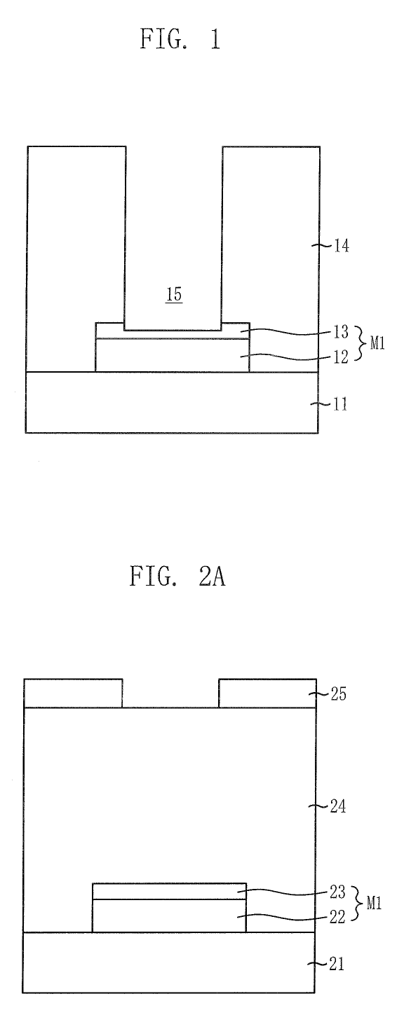

FIGS. 2A to 2C illustrate a method for fabricating a semiconductor device in accordance with an embodiment of the present invention.

FIGS. 3A and 3B are micrographic views of the formation of a contact hole in accordance with an embodiment of the present invention.

FIGS. 4A and 4B illustrate an etching rate of an IMD layer and a titanium nitride layer in accordance with an embodiment of the present invention.

### DESCRIPTION OF SPECIFIC EMBODIMENTS

Hereinafter, a method for fabricating a semiconductor device in accordance with the present invention will be described in detail with reference to the accompanying drawings.

In accordance with embodiments of the present invention, when a stop on titanium nitride (SOT) for metal lines is implemented in forming a contact hole for interconnection between the metal lines, a punch phenomenon from the titanium nitride TiN can be prevented by using a high etching rate with respect to TiN. Further, a contact-not-open phenomenon can be prevented by using a lower etch rate in an overetching process than in the contact hole etching process.

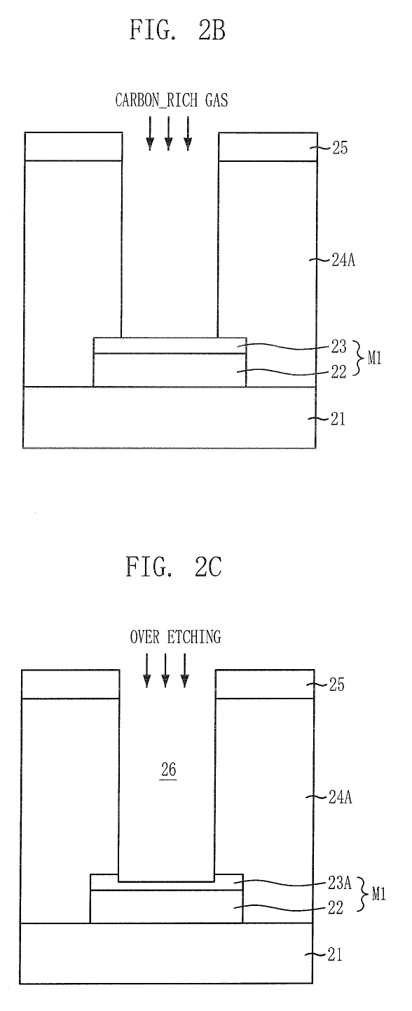

FIGS. 2A to 2C illustrate a method for fabricating a semiconductor device in accordance with an embodiment of the present invention.

Referring to FIG. 2A, a metal line M1 is formed over a substrate 21. The substrate 21 may be a semiconductor substrate (e.g., a silicon substrate) where a dynamic random access memory (DRAM) process is performed, or may be a substrate where a gate, a bit line, a capacitor and the like are formed. The metal line M1 may be formed in a stacked structure of a conductive layer 22 and a barrier layer 23. The conductive layer 22 may be formed of aluminum, and the barrier layer 23 may be formed in a stacked structure of titanium (Ti) and titanium nitride (TiN). Specifically, the barrier layer 23 prevents the conductive layer 22 from being exposed to air, so that the conductive layer 22 will not be oxidized and deteriorated. Further, the barrier layer 23 serves as an anti-reflection layer while patterning the metal line M1. That is, like in an SOT process that stops etching at the titanium nitride layer (i.e., the uppermost layer of the barrier layer 23) and thus prevents the conductive layer 22 from being exposed to air, the etching is stopped at the barrier layer 23 while forming a contact hole, thereby preventing the conductive layer 22 from being exposed to air.

To this end, the barrier layer 23 is formed such that a total thickness of the titanium layer and the titanium nitride layer ranges from approximately 300 Å to approximately 1,500 Å. When the barrier layer 23 is too thin, it may not act as a barrier. When the barrier 23 is too thick, it is difficult to define the metal line due to a deficient etching margin of a mask pattern in patterning the metal line. For example, when a thickness of the barrier layer 23 is approximately 900 Å, a thickness of the titanium layer may be approximately 100 Å and a thickness of the titanium nitride layer may be approximately 800 Å.

An inter-metal dielectric (IMD) layer 24 is formed over the metal line M1. The IMD layer 24 may be a single layer or a multi-layer with at least two layers. The IMD layer may be formed of tetra ethyl ortho silicate (TEOS)-based material, for example, plasma enhanced TEOS (PETEOS) and low plasma TEOS (LPTEOS). The IMD layer 24 may be formed in a stacked structure of a TEOS-based layer, a spin on glass (SOG) oxide layer, and a TEOS-based layer, or a stacked structure of a TEOS-based layer, a high density plasma (HDP) oxide layer, and a TEOS-based layer. The SOG oxide layer is an oxide layer formed by a spin on coating process, and the HDP oxide layer is an oxide layer formed by an HDP process.

A photoresist pattern 25 is formed over the IMD layer 24. More specifically, a photoresist layer (not shown) is coated on the IMD layer 24 and is patterned by an exposure process and a development process to open a contact hole region. As is well known, the exposure process is to expose the photoresist layer to ultraviolet rays to transfer an image of an aligned mask, and the development process is to selectively remove the photoresist layer that is not defined by the masking and the exposure process.

Referring to FIG. 2B, a portion of the IMD layer 24 is etched by using a carbon-rich CF-based gas up to opening the barrier layer 23. The carbon-rich CF-based gas represents a gas having a composition ratio of carbon (C) to fluorine (F) in a range of approximately 1:1 to approximately 1:3. The barrier layer 23 has a lower etching rate with respect to the IMD layer 24. That is, the carbon (C) from the carbon-rich CF-based gas reacts with titanium (Ti) or nitrogen (N) from the titanium nitride layer, which is the uppermost layer of the barrier layer 23, and by-products are formed into a polymer having metallic characteristics. Thus, the etching rate decreases.

In this way, a ratio of etch rates of the IMD layer 24 and the barrier layer 23 can range from approximately 10:1 to approximately 20:1 using the carbon-rich CF-based gas. The CF-based gas may include one selected from the group consisting of C₄F₈, C₄F₆, and C₃F₈ and a combination thereof. Further, since the etching process is performed at a low pressure ranging from approximately 1 mTorr to approximately 50 mTorr, the IMD layer 24 can be well etched. That is, when the etching process is performed at a low pressure, the movement of gases participating in the etching is further activated and thus the etching rate is increased. Reference numeral 24A represents an etched IMD layer after etching by carbon-rich CF-based gas.

Referring to FIG. 2C, a contact hole 26 is formed by overetching the barrier layer 23 to a given depth by using gas containing a smaller amount of carbon than the gas used in the etching of the IMD layer 24. The overetching process is an additional etching process that etches a portion of the barrier layer 23 so as to prevent a contact-not-open phenomenon, which is caused when an etch stop occurs due to a lower etch rate of the barrier layer 23 in etching the IMD layer 24. Since the overetching process is performed in a state where the barrier layer 23 has a higher etching rate than the etching rate of the barrier layer 23 in the etching of the IMD layer 24, appropriate loss of the barrier layer 23 may occur. The overetching process may be performed by using a etch target to provide the barrier layer 23 with a thickness ranging from approximately 160 Å to approximately 840 Å. When the thickness of the barrier layer 23 is approximately 900 Å, the overetching process is performed such that the thickness of the barrier layer 23 is reduced to have a thickness of approximately 500 Å.

The overetching process may cause an appropriate loss of the barrier layer 23 by applying a gas having a smaller amount of carbon than the gas used in the etching of the IMD layer 24 and applying a higher pressure than the pressure used in the etching of the IMD layer 24. For example, the overetching process may be performed by using CF₄ gas or CHF₃ gas and applying a middle pressure of approximately 50 mT to approximately 200 mT.

In this way, a ratio of etch rates of the IMD layer 24 and the barrier layer 23 can range from approximately 1:1 to approximately 10:1 using the gas containing a small amount of carbon and applying a high pressure. A reference numeral 23A represents the etched barrier layer 23.

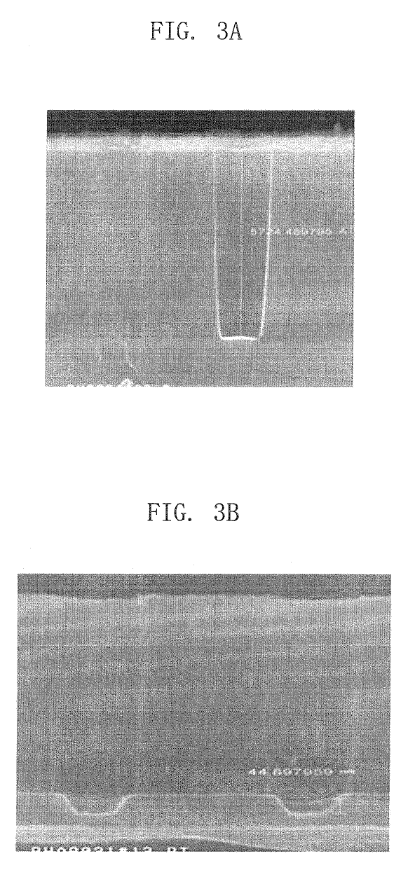

FIGS. 3A and 3B illustrate micrographic views of the formation of the contact hole in accordance with an embodiment of the present invention.

FIG. 3A shows the semiconductor device after the contact hole etching process performed by using the carbon-rich CF-based gas. Since the IMD layer is etched by using the carbon-rich CF-based gas such that the IMD layer has a much higher etching rate than that of the titanium nitride layer, the etching is stopped at the titanium nitride layer after the etching of the IMD layer. Since the IMD layer has a higher etching rate in the carbon-rich CF-based gas, the punch phenomenon of the titanium nitride layer, i.e., the barrier layer, can be prevented.

Referring to FIG. 3B, the titanium nitride layer is appropriately lost after the overetching process. Since the overetching process is performed such that the titanium nitride layer has a higher etching rate than the etching rate of the titanium nitride layer in the etching of the IMD layer by using a gas containing a smaller amount of carbon than the gas used in the etching of the IMD layer, the titanium nitride layer is appropriately lost, thereby preventing a contact-not-open phenomenon.

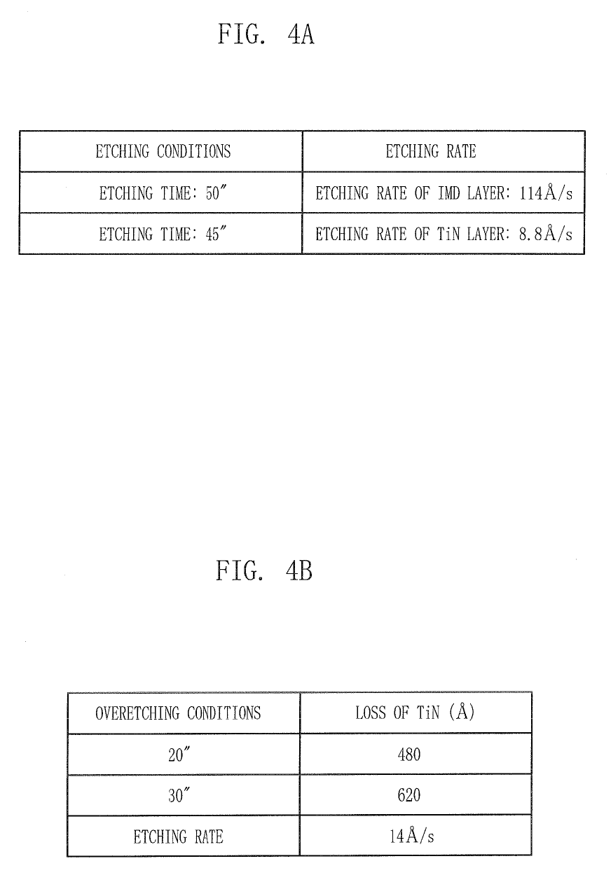

FIGS. 4A and 4B illustrate an etching rate of the IMD layer and the titanium nitride layer in accordance with an embodiment of the present invention.

Referring to FIG. 4A, the etching rate of the IMD layer was 114 Å/sec when the etching process was performed for 50 seconds using the carbon-rich gas used in the contact hole etching process, and the etching was performed to 400 Å of titanium nitride layer when the titanium nitride layer was continuously performed for 45 seconds. Thus, the etching rate of the titanium nitride layer was 8.8 Å/sec. Therefore, a ratio of etch rates of the IMD layer and the titanium nitride layer is approximately 12:1 or more. Consequently, the punch phenomenon of the titanium nitride layer can be prevented.

Referring to FIG. 4B, when the etching process was performed for 20 seconds using the gas (e.g., CF₄ or CHF₃) used in the overetching process, the titanium nitride layer was lost by 480 Å and then the etching process was continuously performed for 10 seconds more (etching is performed for 30 seconds total), the titanium nitride layer was reduced by 620 Å. Therefore, the titanium nitride layer was reduced by 140 Å for 10 seconds. Thus, the etching rate of the titanium nitride layer was 14 Å/sec. Consequently, the contact-not-open phenomenon can be prevented because the titanium nitride layer is appropriately lost by the overetching process.

As described above, since the IMD layer 24 is etched by using the carbon-rich CF-based gas, the low etching rate of the barrier layer 23 can be obtained. Compared with the etching of the IMD layer 24, a smaller amount of carbon and higher pressure are used in the overetching process so that the etch rate of the barrier layer 23 is increased. Therefore, the punch phenomenon of the barrier layer 23 can be prevented and the contact-not-open phenomenon can be prevented due to an appropriate loss of the barrier layer 23.

While the present invention has been described with respect to the specific embodiments, the above embodiments of the present invention are illustrative and not limitative. It will be apparent to those skilled in the art that various changes and modifications may be made without departing from the spirit and scope of the invention as defined in the following claims.

What is claimed is:

1. A method for fabricating a semiconductor device, the method comprising:
forming a metal line over a substrate, the metal line having a stacked structure including a conductive layer and a barrier layer;
forming an inter-metal dielectric layer over the barrier layer;
etching the inter-metal dielectric layer by using a first etch gas to expose the barrier layer, the first etch gas including a carbon-rich CF-based gas; and
etching the exposed barrier layer to a given depth by using a second etch gas, the second etch gas being less carbon rich than the first etch gas.

2. The method as recited in claim 1, wherein the barrier layer has a stacked structure including a titanium layer and a titanium nitride layer.

3. The method as recited in claim 1, wherein the first etch gas has a composition ratio of carbon to fluorine in a range from approximately 1:1 to approximately 1:3.

4. The method as recited in claim 3, wherein the first etch gas comprises one selected from the group consisting of C₄F₈, C₄F₆, and C₃F₈ and a combination thereof.

5. The method as recited in claim 2, wherein a ratio of etch rates of the inter-metal dielectric layer and the barrier layer in the etching of the inter-metal dielectric layer ranges from approximately 10:1 to approximately 20:1.

6. The method as recited in claim 5, wherein the etching of the inter-metal dielectric layer is performed at a pressure ranging from approximately 1 mTorr to approximately 50 mTorr.

7. The method as recited in claim 2, wherein a ratio of etch rates of the inter-metal dielectric layer and the barrier layer in the overetching of the barrier layer ranges from approximately 1:1 to approximately 10:1.

8. The method as recited in claim 7, wherein the second etch gas CF₄ or CHF₃, or both.

9. The method as recited in claim 8, wherein the barrier layer is etched under a pressure ranging from approximately 50 mTorr to approximately 200 mTorr.

10. The method as recited in claim 1, wherein the conductive layer comprises aluminum.

11. The method as recited in claim 1, wherein the barrier layer has a thickness ranging from approximately 300 Å to approximately 1,500 Å.

12. The method as recited in claim 11, wherein of the barrier layer is etched using the second etch gas to have a thickness ranging from approximately 160 Å to approximately 840 Å.

13. The method as recited in claim 1, wherein the inter-metal dielectric layer has a single-layer structure or a multi-layer structure.

14. The method as recited in claim 13, wherein the inter-metal dielectric layer comprises a tetra ethyl ortho silicate (TEOS)-based material.

15. The method as recited in claim 13, wherein the inter-metal dielectric layer comprises a stacked structure including a TEOS-based layer, a spin on glass (SOG) oxide layer, and a TEOS-based layer, or a stacked structure of a TEOS-based layer, a high density plasma (HDP) oxide layer, and a TEOS-based layer.
